(19) United States
(12) Patent Application Publication
(10) Pub. No.: US 2026/0024956 A1
(43) Pub. Date: Jan. 22, 2026

(54) LIGHT-EMITTING DEVICE

(71) Applicant: NICHIA CORPORATION, Anan-shi (JP)

(72) Inventors: Keisuke FUJIWARA, Anan-shi (JP); Masatoshi NAKAGAKI, Komatsushima-shi (JP)

(21) Appl. No.: 19/269,013

(22) Filed: Jul. 14, 2025

(30) Foreign Application Priority Data
Jul. 19, 2024 (JP) 2024-115459

(51) Int. Cl. H01S 5/02253; H01S 5/02255; H01S 5/02257; H01S 5/02315; H01S 5/042

(52) U.S. Cl. CPC H01S 5/02253; H01S 5/02255; H01S 5/02257; H01S 5/02315; H01S 5/04256

(57) ABSTRACT

A light-emitting device includes a base, a semiconductor laser element, a support member, a light-reflecting member, and a lens. The base includes a main body defining a recessed portion, and a step member provided inside the recessed portion. The lens is disposed on the upper surface of the step member above the light-reflecting member. The lens includes a planar portion and a convex surface portion located above the planar portion. When, in the top view, an elongated direction of the step member is a first direction, a length of the lens in the first direction is shorter than a length of the lens in a second direction orthogonal to the first direction. In the top view, at least a portion of the semiconductor laser element does not overlap the lens.

### CROSS-REFERENCE TO RELATED APPLICATION

This application claims priority to Japanese Patent Application No. 2024-115459, filed on Jul. 19, 2024, the disclosure of which is hereby incorporated herein by reference in its entirety.

### TECHNICAL FIELD

The present disclosure relates to a light-emitting device.

### BACKGROUND

Japanese Patent Publication No. 2020-136386 discloses a light-emitting device including a base having a recessed portion, a submount disposed on a bottom surface of the recessed portion, a semiconductor laser element disposed on the submount, a light-reflecting member that is disposed on the bottom surface of the recessed portion and reflects light from the semiconductor laser element, a light-transmissive member disposed on an upper surface of the base, and a lens member disposed above the light-transmissive member.

### SUMMARY

An object of the present disclosure is to provide a light-emitting device in which a relative positional relationship between laser light emitted by a semiconductor laser element and a lens is easily adjusted.

A light-emitting device according to an embodiment of the present disclosure includes a base, a semiconductor laser element, a support member, a light-reflecting member, and a lens. The base includes a main body defining a recessed portion opening at an upper surface of the main body, and a step member provided inside the recessed portion, extending along an inner lateral surface of the recessed portion, and disposed between a bottom surface of the recessed portion and the upper surface of the main body in a height direction. The semiconductor laser element is disposed between the bottom surface of the recessed portion and an upper surface of the step member in the height direction, and configured to emit laser light. The support member is disposed on the bottom surface of the recessed portion and supports the semiconductor laser element. The light-reflecting member is disposed on the bottom surface of the recessed portion, spaced apart from the support member and the semiconductor laser element, and configured to reflect upwardly the laser light emitted by the semiconductor laser element. The lens is disposed on the upper surface of the step member such that the lens is located above the light-reflecting member. The lens includes a planar portion including a region overlapping the upper surface of the step member and a region overlapping the light-reflecting member in a top view, and a region on which the laser light having been reflected by the light-reflecting member is incident, a convex surface portion located above the planar portion, and including a region through which the laser light incident from the planar portion exits. When, in the top view, an elongated direction of the step member is referred to as a first direction, a length of the lens in the first direction is shorter than a length of the lens in a second direction orthogonal to the first direction. In the top view, at least a portion of the semiconductor laser element does not overlap the lens.

According to an embodiment of the present disclosure, a light-emitting device in which a relative positional relationship between laser light emitted by a semiconductor laser element and a lens is easily adjusted can be provided.

### BRIEF DESCRIPTION OF DRAWINGS

FIG. 1 is a schematic top view illustrating a light-emitting device according to an embodiment.

FIG. 2 is a schematic top view illustrating the light-emitting device according to the embodiment, in which a light-transmissive member and a reflecting mirror are omitted.

FIG. 3 is a schematic cross-sectional view of the light-emitting device according to the embodiment taken along a line III-III in FIG. 1.

FIG. 4 is a partially enlarged schematic cross-sectional view illustrating a portion of the light-emitting device according to the embodiment in a region IV in FIG. 3.

FIG. 5 is a partially enlarged schematic cross-sectional view illustrating a portion of a light-emitting device according to a reference example.

FIG. 6 is a schematic top view illustrating a light-emitting device according to a first modified example of the embodiment.

FIG. 7 is a schematic top view illustrating another example of the light-emitting device according to the first modified example of the embodiment.

FIG. 8 is a schematic perspective view illustrating a light-emitting device according to a second modified example of the embodiment.

FIG. 9 is a schematic top view illustrating the light-emitting device according to the second modified example of the embodiment.

FIG. 10 is a schematic perspective view illustrating a light-emitting device according to a third modified example of the embodiment.

FIG. 11 is a schematic top view illustrating the light-emitting device according to the third modified example of the embodiment.

### DETAILED DESCRIPTIONS

Light-emitting devices according to embodiments of the present disclosure are described in detail below with reference to the drawings. However, the following embodiments are examples of light-emitting devices for embodying the technical concept of the embodiments, and the present disclosure is not limited to the following embodiments. The dimensions, materials, shapes, relative arrangements, and the like of the components described in the embodiments are not intended to limit the scope of the present disclosure, but are merely illustrative examples, unless otherwise specifically stated. Note that the sizes, positional relationship, or the like of members illustrated in the drawings may be exaggerated for clarity of description. In addition, in the following description, members having the same terms and reference characters represent the same or similar members, and detailed description of these members is omitted as appropriate. As a cross-sectional view, an end view illustrating only a cut surface may be used.

In the following drawings, directions may be indicated by an X axis, a Y axis, and a Z axis. The X axis, the Y axis, and the Z axis are orthogonal to each other. In the present specification, a direction along the Y axis is referred to as a “first direction Y”. A direction along the X axis is referred to as a “second direction X”. A direction along the Z axis is referred to as a “third direction Z”. The third direction Z corresponds to a height direction. The direction in the first direction Y in which an arrow points is denoted as a +Y direction or a +Y side and the opposite direction to the +Y direction is denoted as a −Y direction or a −Y side. The direction in the second direction X in which an arrow points is denoted as a +X direction or a +X side and the opposite direction to the +X direction is denoted as a −X direction or a −X side. The direction in the third direction Z in which an arrow points is denoted as a +Z direction or a +Z side and the opposite direction to the +Z direction is denoted as a −Z direction or a −Z side. In addition, the +Z direction or the +Z side corresponds to “upward”, and the −Z direction or the −Z side corresponds to “downward”. In addition, in the third direction Z, a surface of a target object when viewed from the +Z direction or the +Z side is referred to as an “upper surface”, and a surface of the target object when viewed from the −Z direction or the −Z side is referred to as a “lower surface”. In addition, in the present specification, a “top view” is referred to as a view of an object from the +Z direction or the +Z side. However, these directions are for convenience of description and do not limit the orientation of the light-emitting device during use. The orientation of the light-emitting device is arbitrary. In the following embodiments, “along the first direction Y, the second direction X and the third direction Z” includes an object having an inclination within a range of ±5° with respect to these directions. In the embodiments, the orthogonality may include an error within ±5° with respect to 90°.

In the present disclosure, a polygon such as a rectangle will be referred to as a polygon, including shapes in which the corners of the polygon are rounded, chamfered, beveled, coved, and the like, unless otherwise specified. A shape obtained by processing not only the corners (ends of a side) but also an intermediate portion of the side is similarly referred to as a polygon. That is, a shape that is partially processed while maintaining the polygon as the base is included in the interpretation of the “polygon” described in the present disclosure.

The same applies to terms describing specific shapes, such as trapezoids, circles, and protrusions and recessions, and terms relating to the sides that form the shapes. That is, even when processing is performed on a corner or an intermediate portion of a certain side or a circumference, the interpretation of “side” and “circumference” includes the processed portion.

The term “to cover” or “covering” is not limited to cases of direct contact, but also includes cases of indirect covering, e.g., through other members. The term “to dispose” is not limited to cases of direct contact, but also includes cases of indirect disposing, e.g., through other members.

### EMBODIMENT

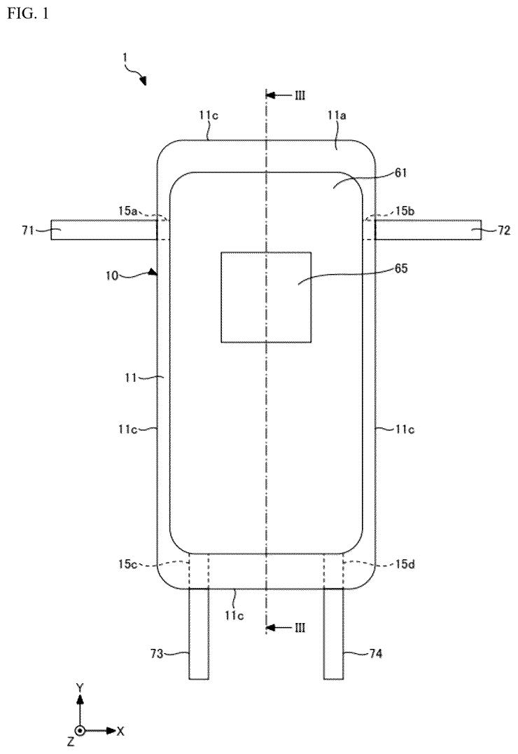

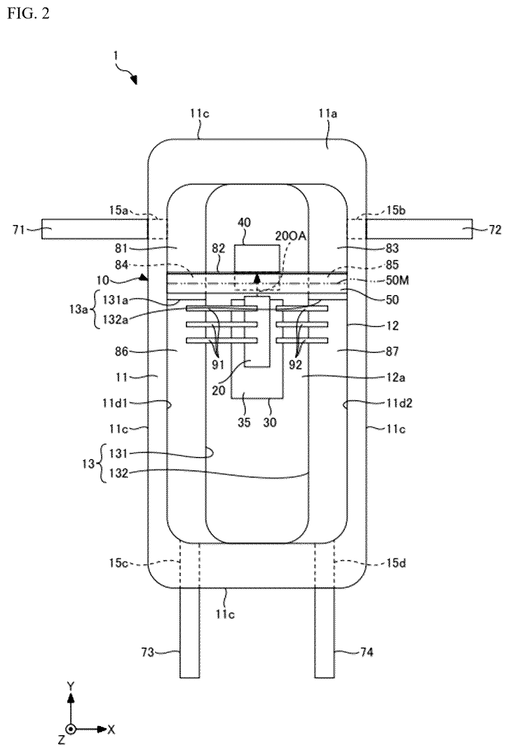

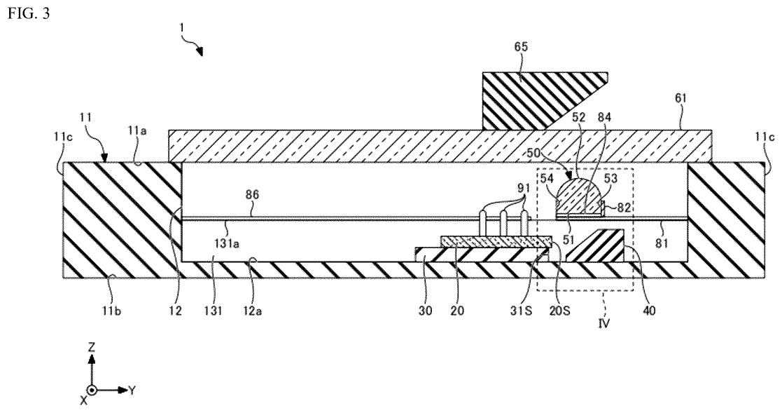

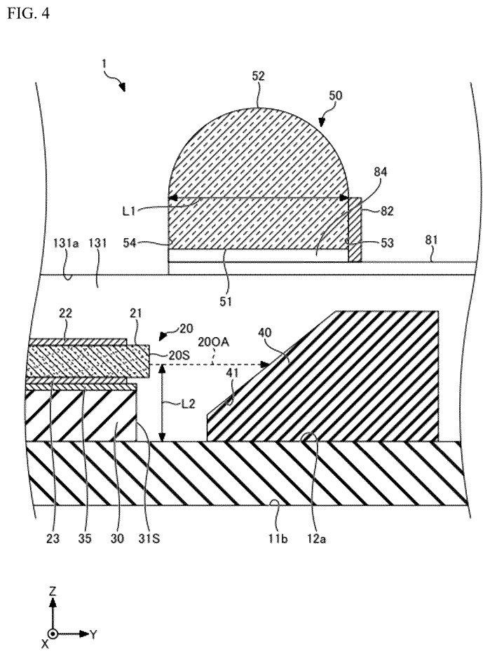

An example of an overall configuration of a light-emitting device 1 according to an embodiment will be described with reference to FIGS. 1 to 4. FIG. 1 is a schematic top view illustrating the light-emitting device 1 according to the embodiment. FIG. 2 is a schematic top view illustrating the light-emitting device according to the embodiment, in which a light-transmissive member 61 and a reflecting mirror 65 are not drawn. FIG. 3 is a schematic cross-sectional view of the light-emitting device 1 according to the embodiment taken along a line III-III in FIG. 1. FIG. 4 is a partially enlarged schematic cross-sectional view illustrating a portion of the light-emitting device 1 according to the embodiment in a region IV in FIG. 3.

As illustrated in FIGS. 1 to 4, the light-emitting device 1 includes a base 10, a semiconductor laser element 20, a support member 30, a light-reflecting member 40, and a lens 50. In addition, the light-emitting device 1 may further include other components such as the light-transmissive member 61, the reflecting mirror 65, a first terminal 71, a second terminal 72, a third terminal 73, a fourth terminal 74, a first conductor 81, a second conductor 82, a third conductor 83, a fourth conductor 84, a fifth conductor 85, a sixth conductor 86, a seventh conductor 87, and fine conductive wires 91 and 92.

As will be described separately, the lens 50 is disposed on an upper surface 13a of a step member 13 included in the base 10. The first terminal 71, the second terminal 72, the first conductor 81, the second conductor 82, and the third conductor 83 serve as a path through which a first current for detecting whether or not the lens 50 is disposed on the upper surface 13a of the step member 13 flows. Hereinafter, the first terminal 71, the second terminal 72, the first conductor 81, the second conductor 82, and the third conductor 83 may be collectively referred to as “members serving as the path of the first current”. The fourth conductor 84 and the fifth conductor 85 may also be included in the path through which the first current flows. In addition, the third terminal 73, the fourth terminal 74, the sixth conductor 86, and the seventh conductor 87 serve as a path through which a second current for supplying power to the semiconductor laser element 20 flows. Hereinafter, the third terminal 73, the fourth terminal 74, the sixth conductor 86, and the seventh conductor 87 may be collectively referred to as “members serving as the path of the second current”.

### Base 10

A configuration example of the base 10 will be described below. As illustrated in FIGS. 1 to 4, the base 10 includes a main body 11, a recessed portion 12, and the step member 13. As illustrated in FIGS. 1 and 2, the base 10 may further include other components such as inner layer wirings 15a, 15b, 15c, and 15d provided inside the main body 11. The inner layer wiring 15a may be a portion of the first terminal 71 or may be provided as a member different from the first terminal 71. The inner layer wiring 15b may be a portion of the second terminal 72 or may be provided as a member different from the second terminal 72. The inner layer wiring 15c may be a portion of the third terminal 73 or may be provided as a member different from the third terminal 73. The inner layer wiring 15d may be a portion of the fourth terminal 74 or may be provided as a member different from the fourth terminal 74. Although four inner layer wirings 15a, 15b, 15c, and 15d are illustrated in FIGS. 1 and 2, the number of inner layer wirings is not limited thereto. The locations and sizes of the inner layer wirings 15a, 15b, 15c, and 15d are not limited to those illustrated in FIGS. 1 and 2.

As illustrated in FIGS. 1 to 3, the main body 11 includes an upper surface 11a, a lower surface 11b, and one or more lateral surfaces 11c in contact with the upper surface 11a and the lower surface 11b. The main body 11 has a substantially rectangular shape in a top view. However, the shape of the main body 11 in a top view is not limited to the substantially rectangular shape. The shape of the main body 11 in a top view may be a shape other than the substantially rectangular shape, such as a substantially circular shape, a substantially elliptical shape, or a substantially polygonal shape excluding the rectangular shape.

The main body 11 is preferably formed of a material such as a ceramic, for example, aluminum nitride, silicon nitride, aluminum oxide, or silicon carbide. However, the main body 11 may be formed of a material other than the ceramics. For example, the main body 11 may be formed of a metal such as copper.

The main body 11 defines the recessed portion 12 that opens at the upper surface 11a of the main body 11. In more detail, as illustrated in FIG. 3, the recessed portion 12 is recessed from the upper surface 11a of the main body 11 toward the −Z side. In a top view, the semiconductor laser element 20, the support member 30, the light-reflecting member 40, and the lens 50 are disposed inside the recessed portion 12. The recessed portion 12 has a bottom surface 12a as a surface located farthest in the −Z direction.

The step member 13 is provided inside the recessed portion 12, and is disposed between the bottom surface 12a of the recessed portion 12 and the upper surface 11a of the main body 11 in the third direction Z. The step member 13 is disposed extending along inner lateral surfaces (inner lateral surfaces including inner lateral surfaces 11d1 and 11d2 which will be described separately) of the recessed portion 12. In the example illustrated in FIG. 2, the step member 13 is elongated in the first direction Y. The step member 13 includes the upper surface 13a which is a surface parallel to each of the first direction Y and the second direction X. The step member 13 includes a lateral surface in contact with the upper surface 13a and the bottom surface 12a of the recessed portion 12. In the base 10, the step member 13 may be a member physically monolithic with the main body 11 or may be a member physically different from the main body 11.

In the example illustrated in FIG. 2, the step member 13 includes a first step member 131 and a second step member 132. The first step member 131 and the second step member 132 are separated from each other in the second direction X and disposed such that the semiconductor laser element 20 is interposed therebetween in a top view. As illustrated in FIG. 2, the first step member 131 protrudes toward the +X side from the inner lateral surface 11d1 of the main body 11 that defines the recessed portion 12. The second step member 132 protrudes toward the −X side from the inner lateral surface 11d2 of the main body 11 that defines the recessed portion 12. Of the upper surface 13a of the step member 13, an upper surface of the first step member 131 is hereinafter referred to as an “upper surface 131a”. In addition, of the upper surface 13a of the step member 13, an upper surface of the second step member 132 is hereinafter referred to as an “upper surface 132a”.

### Semiconductor Laser Element 20

Next, a configuration example of the semiconductor laser element 20 will be described. As illustrated in FIG. 3, the semiconductor laser element 20 is disposed between the bottom surface 12a of the recessed portion 12 and the upper surface 13a of the step member 13 in the third direction Z. As illustrated in FIG. 4, the semiconductor laser element 20 is preferably bonded to the support member 30 via a conductive bonding member 35. By being bonded via the conductive bonding member 35, the semiconductor laser element 20 can be supplied with a current via the bonding member 35.

As illustrated in FIG. 4, the semiconductor laser element 20 includes a semiconductor structure 21, a first electrode 22, and a second electrode 23. In the example illustrated in FIG. 4, the second electrode 23, the semiconductor structure 21, and the first electrode 22 are layered in this order in the third direction Z. However, the positional relationship of the semiconductor structure 21, the first electrode 22, and the second electrode 23 is not limited thereto.

The semiconductor structure 21 includes an upper surface, a lower surface, and one or more lateral surfaces in contact with the upper surface and the lower surface. The semiconductor structure 21 emits light to the +Y side. When the semiconductor structure 21 has a rectangular shape, the light emitted by the semiconductor structure 21 is emitted from a lateral surface located on the +Y side among the one or more lateral surfaces of the semiconductor structure 21. Hereinafter, the lateral surface on the +Y side of the semiconductor structure 21 is referred to as a “light-emitting end surface 20S” of the semiconductor laser element 20.

The semiconductor laser element 20 emits laser light. Light (laser light) emitted from the semiconductor laser element 20 has divergence and forms an elliptical far field pattern (hereinafter referred to as “FFP”) on a plane parallel to the light-emitting end surface 20S. Here, the FFP indicates a shape and light intensity distribution of the light at a location away from the light-emitting end surface 20S. Further, an optical path of light traveling through the center of the elliptical shape of the FFP is referred to as an “optical axis 20OA” of the light, and light passing through the center of the elliptical shape of the FFP, in other words, light having a peak intensity in the light intensity distribution of the FFP is referred to as “light traveling through the optical axis 20OA” or “light passing through the optical axis 20OA”.

The semiconductor structure 21 includes a first semiconductor layer, an active layer, and a second semiconductor layer. The first semiconductor layer is disposed farthest in the +Z direction in the semiconductor structure 21. An upper surface of the first semiconductor layer defines an upper surface of the semiconductor structure 21. The second semiconductor layer is disposed farthest in the −Z direction in the semiconductor structure 21. A lower surface of the second semiconductor layer defines a lower surface of the semiconductor structure 21. The active layer is disposed between the first semiconductor layer and the second semiconductor layer in the third direction Z.

One of the first semiconductor layer and the second semiconductor layer is an n-type semiconductor layer. The other one of the first semiconductor layer and the second semiconductor layer is a p-type semiconductor layer. The active layer may have a single quantum well (SQW) structure, or may have a multiple quantum well (MQW) structure including a plurality of well layers. Each of the first semiconductor layer, the active layer, and the second semiconductor layer in the semiconductor structure 21 is formed of, for example, a nitride-based semiconductor, such as In_{X}Al_{Y}Ga_{1-X-Y}N (0≤X, 0≤Y, X+Y≤1). However, the material constituting each of the first semiconductor layer, the active layer, and the second semiconductor layer is not limited to the nitride-based semiconductor.

The first electrode 22 is disposed on the upper surface of the semiconductor structure 21. The first electrode 22 is electrically connected to the first semiconductor layer. In a case in which the first semiconductor layer is the n-type semiconductor layer, the first electrode 22 corresponds to an n-side electrode. In a case in which the first semiconductor layer is the p-type semiconductor layer, the first electrode 22 corresponds to a p-side electrode. In addition, the first electrode 22 is electrically connected to, for example, the fine conductive wire 91 such as a bonding wire. The fine conductive wire 91 electrically connects the sixth conductor 86 on the upper surface 131a of the first step member 131 and the first electrode 22.

Examples of the material constituting the first electrode 22 include a single metal material such as gold, silver, aluminum, nickel, rhodium, copper, titanium, platinum, palladium, molybdenum, chromium, or tungsten, or an alloy material containing any of these metals. However, the material constituting the first electrode 22 is not limited thereto. In addition, the first electrode 22 may have a single-layer structure formed of a single metal material or an alloy material, or may have a layered structure in which a plurality of metal materials or alloy materials are layered in the third direction Z.

The second electrode 23 is disposed on the lower surface of the semiconductor structure 21. The second electrode 23 is electrically connected to the second semiconductor layer. In a case in which the second semiconductor layer is the p-type semiconductor layer, the second electrode 23 corresponds to the p-side electrode. In a case in which the second semiconductor layer is the n-type semiconductor layer, the second electrode 23 corresponds to the n-side electrode. As illustrated in FIG. 4, a lower surface of the second electrode 23 is bonded to an upper surface of the bonding member 35. The second electrode 23 is electrically connected to, for example, the fine conductive wire 92 such as a bonding wire through the bonding member 35. The fine conductive wire 92 electrically connects the seventh conductor 87 on an upper surface 132a of the second step member 132 and the upper surface of the bonding member 35. Note that the bonding member 35 includes a region to which the semiconductor laser element 20 is physically bonded and a region to which the fine conductive wire 92 is physically bonded. In the bonding member 35, the region to which the semiconductor laser element 20 is physically bonded and the region to which the fine conductive wire 92 is physically bonded may be monolithically formed or may be separated from each other. In a case in which the region to which the semiconductor laser element 20 is physically bonded and the region to which the fine conductive wire 92 is physically bonded are separated from each other, these regions may be electrically connected to each other through the interior of the support member 30.

The second electrode 23 may be formed of a metal material or an alloy material the same as or similar to that of the first electrode 22. In addition, like the first electrode 22, the second electrode 23 may have a single-layer structure formed of a single metal material or an alloy material, or may have a layered structure in which a plurality of metal materials or alloy materials are layered in the third direction Z.

### Support Member 30

Next, a configuration example of the support member 30 will be described. The support member 30 is disposed on the bottom surface 12a of the recessed portion 12 and supports the semiconductor laser element 20. As illustrated in FIGS. 1 to 4, the support member 30 has an upper surface, a lower surface, and one or more lateral surfaces in contact with the upper surface and the lower surface. As illustrated in FIGS. 3 and 4, the upper surface of the support member 30 is bonded to a lower surface of the bonding member 35, for example. In addition, the lower surface of the support member 30 is bonded to the bottom surface 12a of the recessed portion 12.

The support member 30 is, for example, a submount. However, the support member 30 is not limited to the submount. For example, the support member 30 may be a protruding portion in which a portion of the bottom surface 12a of the recessed portion 12 protrudes toward the +Z side. In this case, the semiconductor laser element 20 is, for example, placed on the protruding portion of the bottom surface 12a corresponding to the support member 30 via the bonding member 35.

Hereinafter, the support member 30 as the submount will be described. As illustrated in FIG. 4, a lateral surface 31S on the +Y side of the support member 30 is preferably located on the −Y side with respect to the light-emitting end surface 20S of the semiconductor laser element 20. That is, the light-emitting end surface 20S of the semiconductor laser element 20 is located so as to protrude from the lateral surface 31S on the +Y side of the support member 30 in a top view. Because the light-emitting end surface 20S of the semiconductor laser element 20 protrudes from the lateral surface 31S on the +Y side of the support member 30, the overlap of the support member 30 with the irradiation range of light emitted from the light-emitting end surface 20S can be suppressed. This can suppress a decrease in the intensity of light in a desired irradiation range, a disturbance in a light distribution pattern, or the like caused by the reflection of the light emitted from the semiconductor laser element 20 by the support member 30.

Examples of the material constituting the support member 30 include ceramics such as silicon nitride, aluminum nitride, and silicon carbide and metals such as copper, both of which exhibit good heat dissipation properties. By forming the support member 30 with use of any of these materials, the heat generated by the semiconductor laser element 20 that performs the light emitting operation can be efficiently transferred to the main body 11 of the base 10, and the like. Thus, the influence on the light emission efficiency of the semiconductor laser element 20 due to an excessive increase in the temperature of the semiconductor laser element 20 and the support member 30 can be reduced. However, the material constituting the support member 30 is not limited thereto.

### Light-Reflecting Member 40

Next, a configuration example of the light-reflecting member 40 will be described. The light-reflecting member 40 reflects the light emitted by the semiconductor laser element 20 to the +Z side. As illustrated in FIGS. 2 to 4, the light-reflecting member 40 is disposed on the bottom surface 12a of the recessed portion 12 so as to be separated from the semiconductor laser element 20 and the support member 30.

The light-reflecting member 40 has a light-reflective surface 41, a lower surface, and one or more lateral surfaces in contact with the light-reflective surface 41 and the lower surface. The light-reflecting member 40 may have an upper surface in contact with the light-reflective surface 41 and the one or more lateral surfaces. The light-reflective surface 41 faces the light-emitting end surface 20S of the semiconductor laser element 20. In the example illustrated in FIGS. 3 and 4, the light-reflective surface 41 is an inclined surface, but may be a curved surface such as a convex surface or a concave surface. The light-reflective surface 41 may be formed of quartz, glass such as BK7 (borosilicate glass), a metal such as aluminum or silver, silicon, a dielectric multilayer film, or the like.

An upper end of the light-reflecting member 40 is preferably located on the −Z side with respect to the upper surface 13a of the step member 13. In more detail, an upper end of the light-reflective surface 41 and an upper surface of the light-reflecting member 40 are located on the −Z side with respect to the upper surface 13a of the step member 13. Because the upper end of the light-reflecting member 40 is located on the −Z side with respect to the upper surface 13a of the step member 13, when the lens 50 is disposed on the +Z side with respect to the light-reflecting member 40 and on the upper surface 13a of the step member 13, the likelihood of the lens 50 coming into contact with the light-reflecting member 40 can be reduced.

As illustrated in FIG. 2, the light-reflecting member 40 includes a region overlapping the lens 50 and a region not overlapping the lens 50 in a top view. Because the light-reflecting member 40 includes a region that does not overlap the lens 50 in a top view, it can be easily confirmed that the light-reflecting member 40 is appropriately disposed at a desired location in the design. Note that the light-reflecting member 40 does not necessarily have to include a region that does not overlap the lens 50 in a top view.

### Lens 50

Next, a configuration example of the lens 50 will be described. The lens 50 is disposed on the upper surface 13a of the step member 13 so as to be located on the +Z side with respect to the light-reflecting member 40. In the example illustrated in FIG. 2, the lens 50 is supported by each of the upper surface 131a of the first step member 131 and the upper surface 132a of the second step member 132. In a top view, a length of the lens 50 in the first direction Y is shorter than a length of the lens 50 in the second direction X. Note that the length of the lens 50 in the first direction Y refers to a distance in the first direction Y between a point farthest in the −Y direction and a point farthest in the +Y direction of the lens 50 in a top view. In addition, the length of the lens 50 in the second direction X refers to a distance in the second direction X between a point farthest in the −X direction and a point farthest in the +X direction of the lens 50 in a top view.

The lens 50 includes a planar portion 51 and a convex surface portion 52. The lens 50 may further include lens lateral surfaces 53 and 54 in contact with the planar portion 51 and the convex surface portion 52. Each of the lens lateral surface 53 and the lens lateral surface 54 extends parallel to the third direction Z. In addition, the lens lateral surface 53 and the lens lateral surface 54 are separated from each other in the first direction Y and are disposed facing each other, for example. The lens lateral surface 53 connects outer edges of the planar portion 51 and the convex surface portion 52 on the +Y side. The lens lateral surface 54 connects the outer edges of the planar portion 51 and the convex surface portion 52 on the −Y side. The lens 50 is, for example, a cylindrical lens. Because the lens 50 is a cylindrical lens, the shape of the convex surface portion 52 of the lens 50 is the same as or similar at any location in the second direction X. That is, the manner in which the lens 50 acts on the light incident on the lens 50 can be made the same as or similar regardless of the location in the second direction X.

For example, the lens 50 reduces the divergence angle of the light travelling in the first direction Y more than the divergence angle of the light travelling in the second direction X among the laser light incident on the planar portion 51 of the lens 50. For example, the lens 50 collimates the light travelling in the first direction Y and does not collimate the light travelling in the second direction X among the laser light incident on the planar portion 51 of the lens 50. With this configuration, a lens which collimates only a necessary direction of the laser light incident on the planar portion 51 of the lens 50 can be obtained. In addition, with this configuration, the size of the lens 50 can be reduced in a direction in which collimation is not necessary, and as a result, the size of the light-emitting device 1 can be reduced. In the present disclosure, among the laser light incident on the planar portion 51 of the lens 50, the light travelling in the first direction Y is a fast-axis light, and the light in the second direction X is a slow-axis light. Thus, in the present disclosure, the lens 50 functions as a fast-axis collimating (FAC) lens.

The planar portion 51 is located farthest in the −Z direction in the lens 50. In addition, the planar portion 51 is a surface extending parallel to each of the first direction Y and the second direction X. The planar portion 51 has a belt-like shape elongated in the second direction X in a top view. That is, the longitudinal direction of the planar portion 51 is parallel to the second direction X, and the short-side direction of the planar portion 51 is parallel to the first direction Y.

The planar portion 51 includes a region overlapping the upper surface 13a of the step member 13 in a top view. In more detail, the planar portion 51 includes a region overlapping the upper surface 131a of the first step member 131 and a region overlapping the upper surface 132a of the second step member 132 in a top view. In the example illustrated in FIG. 2, an end portion of the planar portion 51 on the −X side overlaps the upper surface 131a of the first step member 131 in a top view. That is, the end portion of the planar portion 51 on the −X side is supported by the upper surface 131a of the first step member 131. In addition, an end portion of the planar portion 51 on the +X side overlaps the upper surface 132a of the second step member 132. That is, the end portion of the planar portion 51 on the +X side is supported by the upper surface 132a of the second step member 132. Thus, the lens 50 is stably supported at a location on the +Z side with respect to the light-reflecting member 40.

The planar portion 51 further includes a region on which the light emitted by the semiconductor laser element 20 and reflected by the light-reflecting member 40 is incident. The region of the planar portion 51 on which the light reflected by the light-reflecting member 40 is incident is located between a region overlapping the upper surface 131a of the first step member 131 and a region overlapping the upper surface 132a of the second step member 132 in a top view. The planar portion 51 corresponds to a light incident surface of the lens 50.

The convex surface portion 52 is located farthest in the +Z direction in the lens 50. The convex surface portion 52 is located above the planar portion 51. In addition, the convex surface portion 52 overlaps the planar portion 51 in a top view. The light incident on the lens 50 from the planar portion 51 reaches the convex surface portion 52. The convex surface portion 52 includes a region through which light having entered the interior of the lens 50 from the planar portion 51 exits. That is, the convex surface portion 52 corresponds to the light exit surface of the lens 50.

When the convex surface portion 52 is viewed from the lateral side of the lens 50, that is, from the second direction X, the curvature of the convex surface portion 52 is preferably substantially uniform regardless of the location of the convex surface portion 52 in the second direction X. As illustrated in FIGS. 3 and 4, when viewed from the second direction X, the convex surface portion 52 has a spherical shape. However, when viewed from the second direction X, the convex surface portion 52 may have an aspherical shape.

As illustrated in FIG. 3, the most protruding portion of the convex surface portion 52 is preferably located on the −Z side with respect to the upper surface 11a of the main body 11 of the base 10. Because the most protruding portion of the convex surface portion 52 is located on the −Z side with respect to the upper surface 11a of the main body 11, an increase in the length of the light-emitting device 1 in the third direction Z can be suppressed and an increase in the size of the light-emitting device 1 can be suppressed.

In addition, because the most protruding portion of the convex surface portion 52 is located on the −Z side with respect to the upper surface 11a of the main body 11, the convex surface portion 52 and the light-transmissive member 61 are not in contact with each other even when the light-transmissive member 61 is disposed so as to overlap the recessed portion 12 of the base 10 in a top view. That is, using the light-transmissive member 61 to cover the recessed portion 12 from the +Z side is not obstructed by the convex surface portion 52.

The convex surface portion 52 collimates the light having reached the convex surface portion 52 and makes the collimated light exit to the +Z side. Here, in the present specification, the term “collimate” includes not only deflecting light so that it becomes parallel light but also reducing the divergence angle of light.

In a top view, a straight line passing through the center of gravity of the lens 50 and being parallel to the second direction X is defined as a center line 50M. In FIG. 2, the center line 50M of the lens 50 and the optical axis 20OA of the semiconductor laser element 20 are orthogonal to each other in a top view. As a result, the optical effect of the lens 50 on the light emitted from the semiconductor laser element 20 is uniform regardless of the location of the lens 50 in the second direction X, facilitating optical design using the light-emitting device 1. When the lens 50 is a cylindrical body such as a cylindrical lens, the center line 50M is, for example, the generatrix of the lens 50.

As illustrated in FIG. 2, the center line 50M of the lens 50 is orthogonal to the first direction Y in a top view. That is, the center line 50M of the lens 50 is parallel to the second direction X in a top view. In addition, in the lens 50, the direction orthogonal to the center line 50M is parallel to the first direction Y. Hereinafter, in the lens 50, a length in the direction orthogonal to the center line 50M is referred to as a “length L1 of the lens 50 in the first direction Y” (see FIG. 4).

In a top view, the length L1 of the lens 50 in the first direction Y is at least twice a length L2 from the bottom surface 12a of the recessed portion 12 to the optical axis 20OA of the light emitted by the semiconductor laser element 20 in the third direction Z. In the example illustrated in FIG. 4, the length L1 of the lens 50 in the first direction Y is at least twice the length from the bottom surface 12a of the recessed portion 12 to the lower surface of the second electrode 23 of the semiconductor laser element 20 in the third direction Z.

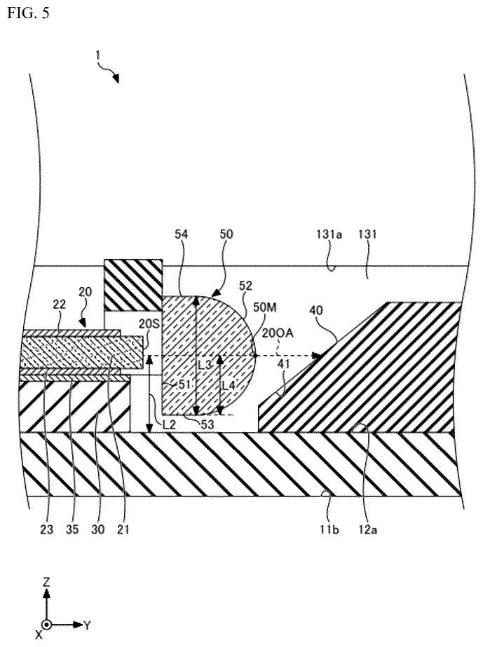

A reference example in which the lens 50 is provided such that the planar portion 51 and the light-emitting end surface 20S of the semiconductor laser element 20 are parallel to each other unlike in the present disclosure will be described with reference to FIG. 5. FIG. 5 is a partially enlarged schematic cross-sectional view illustrating a portion of the light-emitting device according to a reference example. In the reference example illustrated in FIG. 5, the lens 50 is disposed between the light-emitting end surface 20S of the semiconductor laser element 20 and the light-reflective surface 41 of the light-reflecting member 40 such that the planar portion 51 and the light-emitting end surface 20S face each other. In this case, the length of the lens 50 in the direction (the third direction Z) orthogonal to both the center line 50M and the optical axis of the light emitted by the semiconductor laser element 20 is referred to as a “length L3 of the lens 50 in the third direction Z”. In a case in which the lens 50 is provided such that the planar portion 51 and the light-emitting end surface 20S of the semiconductor laser element 20 are parallel to each other, the length L3 of the lens 50 in the third direction Z corresponds to a length from the +Z side end portion to the −Z side end portion of the planar portion 51. As illustrated in FIG. 5, the length L3 of the lens 50 in the third direction Z may be rephrased as the distance between the lens lateral surface 53 and the lens lateral surface 54 when viewed from the second direction X. In addition, the distance between the center line 50M described below farthest from the planar portion 51 among the center lines 50M of the lens 50 and the lens lateral surface 53 or the lens lateral surface 54 is 0.5 times the length L3 of the lens 50 in the third direction Z (a length “L4” illustrated in FIG. 5). The center line 50M passes through the black dot illustrated in FIG. 5, and overlaps the most protruding portion of the convex surface portion 52. Hereinafter, this center line 50M is simply referred to as the “center line 50M.” The lens 50 is preferably provided such that the optical axis 20OA of the light emitted from the semiconductor laser element 20 is orthogonal to the center line 50M of the lens 50. In a case in which the lens 50 is provided in this manner, to avoid contact between the bottom surface 12a of the recessed portion 12 and the lens lateral surface of the lens lateral surface 53 or the lens lateral surface 54 either of which is close to the bottom surface 12a of the recessed portion 12, the lens lateral surface close to the bottom surface 12a of the recessed portion 12 needs to be disposed at a location (+Z side) higher than the bottom surface 12a. Therefore, the length L4 that is 0.5 times the length L3 of the lens 50 in the third direction Z corresponding to the distance between the center line 50M of the lens 50 and the lens lateral surface 53 or the lens lateral surface 54 cannot be made larger than the length L2 from the bottom surface 12a of the recessed portion 12 to the optical axis 20OA of the light emitted by the semiconductor laser element 20 in the third direction Z. That is, to make the length L3 of the lens 50 in the third direction Z at least twice the length L2 from the bottom surface 12a of the recessed portion 12 to the optical axis 20OA of the light emitted by the semiconductor laser element 20 in the third direction Z, it is necessary to take measures such as increasing the thickness of the support member 30 in the third direction Z to increase the length L2 from the bottom surface 12a of the recessed portion 12 to the optical axis 20OA of the light emitted by the semiconductor laser element 20 in the third direction Z. However, such measures lead to an increase in the size of the light-emitting device 1.

In contrast, in the present disclosure, the lens 50 is not disposed between the light-emitting end surface 20S of the semiconductor laser element 20 and the light-reflective surface 41 of the light-reflecting member 40, but is disposed on the upper surface 13a of the step member 13. Thus, without increasing the length L2 from the bottom surface 12a of the recessed portion 12 to the optical axis 20OA of the light emitted by the semiconductor laser element 20 in the third direction Z, the lens 50 can be disposed at a location on the +Z side with respect to the light-reflecting member 40 such that the length L1 of the lens 50 in the first direction Y is at least twice the length L2 from the bottom surface 12a of the recessed portion 12 to the optical axis 20OA of the light emitted by the semiconductor laser element 20 in the third direction Z. That is, without increasing the length (thickness) of the support member 30 in the third direction Z, a relatively large lens 50 can be used. As a result, the optical path of the light reflected by the light-reflecting member 40 can be adjusted using a relatively large lens 50 as compared with the reference example in which the lens 50 is provided such that the planar portion 51 and the light-emitting end surface 20S of the semiconductor laser element 20 are parallel to each other. By disposing the relatively large lens 50, in a top view, a region in which the lens 50 and the light-reflecting member 40 overlap each other can be increased. As a result, the likelihood of generating the light, of the light reflected by the light-reflecting member 40, that does not pass through the lens 50 and is not collimated can be reduced. In addition, by not increasing the length (thickness) of the support member 30 in the third direction Z, degradation of heat dissipation of the semiconductor laser element 20 caused by the support member 30 can be reduced. That is, by disposing the lens 50 over the upper surface 13a of the step member 13, a relatively large lens 50 can be used without degrading heat dissipation of the semiconductor laser element 20.

In the present disclosure, at least a portion of the semiconductor laser element 20 does not overlap the lens 50 in a top view. With this configuration, even when the lens 50 is provided, the semiconductor laser element 20 can be confirmed in a top view. Therefore, even when the relatively large lens 50 is provided, a mounting location and the like of the semiconductor laser element 20 can be confirmed. In addition, with this configuration, the fine conductive wire 91 can be easily provided on an upper surface of the semiconductor laser element 20. In the present disclosure, the length of the lens 50 in the first direction Y is shorter than the length of the lens 50 in the second direction X. With this configuration, moving the lens 50 in the first direction Y on the step member 13 is easy, and adjusting a relative positional relationship between the laser light emitted by the semiconductor laser element 20 and the lens 50 is easy. In the example illustrated in FIG. 2, the length of the step member 13 in the first direction Y (in FIG. 2, at least one of the length of the first step member 131 in the first direction Y and the length of the second step member 132 in the first direction Y) is at least twice the length of the lens 50 in the first direction Y. Because the length of the step member 13 in the first direction Y is at least twice the length of the lens 50 in the first direction Y, the location of the lens 50 with respect to the optical axis 20OA can be freely adjusted within a range in which light along the optical axis 20OA emitted by the semiconductor laser element 20 and reflected by the light-reflecting member 40 is incident on the planar portion 51 of the lens 50.

In the example illustrated in FIG. 2, the lens 50 is disposed to extend across both the first step member 131 and the second step member 132. Thus, the lens 50 can be stably disposed while securing a movable range of the lens 50 in the first direction Y.

In addition, in a top view, the length L1 of the lens 50 in the first direction Y is preferably equal to or less than four times the length L2 from the bottom surface 12a of the recessed portion 12 to the optical axis 20OA of the light emitted from the semiconductor laser element 20 in the third direction Z. By setting the length L1 of the lens 50 in the first direction Y to equal to or less than four times the length L2 from the bottom surface 12a of the recessed portion 12 to the optical axis 20OA of the light emitted by the semiconductor laser element 20 in the third direction Z, an increase in the size of the light-emitting device 1 can be suppressed.

### Light-Transmissive Member 61

Next, a configuration example of the light-transmissive member 61 will be described. The light-transmissive member 61 overlaps the recessed portion 12 of the base 10 in a top view. That is, the light-transmissive member 61 covers the recessed portion 12 from the +Z side. Thus, the semiconductor laser element 20, the light-reflecting member 40, and the lens 50 are accommodated in a space defined by the base 10 and the light-transmissive member 61. In other words, the semiconductor laser element 20, the light-reflecting member 40, and the lens 50 are hermetically sealed by the base 10 and the light-transmissive member 61. Thus, the likelihood of the intrusion of particulate matter such as dust and/or dirt floating outside into the inner side of the recessed portion 12 and adhesion thereof to the members such as the semiconductor laser element 20, the light-reflecting member 40, and the lens 50 can be reduced. That is, by hermetically sealing the semiconductor laser element 20, the light-reflecting member 40, and the lens 50 with the base 10 and the light-transmissive member 61, contamination of the members such as the semiconductor laser element 20, the light-reflecting member 40, and the lens 50 can be reduced. As a result, reliability of the light-emitting device 1 can be improved.

As illustrated in FIG. 3, the light-transmissive member 61 is disposed on the +Z side of the lens 50. The light-transmissive member 61 has transmissivity with respect to the light having exited from the convex surface portion 52 of the lens 50. Here, in the present specification, “transmissivity” refers to the light transmittance of 60% or more, preferably 80% or more. Examples of the material constituting the light-transmissive member 61 include insulating materials such as sapphire, spinel, and glass, and semiconductor materials such as aluminum nitride and silicon carbide. However, the material constituting the light-transmissive member 61 is not limited thereto.

The light having exited from the convex surface portion 52 of the lens 50 and transmitted through the light-transmissive member 61 travels toward the reflecting mirror 65.

### Reflecting Mirror 65

Next, a configuration example of the reflecting mirror 65 will be described. The reflecting mirror 65 is an optical member that reflects the light having exited from the convex surface portion 52 of the lens 50 and transmitted through the light-transmissive member 61 in a predetermined direction. In the example illustrated in FIG. 3, the reflecting mirror 65 is disposed on the light-transmissive member 61. In addition, in the example illustrated in FIG. 3, the reflecting mirror 65 reflects the light having exited from the convex surface portion 52 of the lens 50 and transmitted through the light-transmissive member 61 to the +Y side. However, the location of the reflecting mirror 65 and the reflection direction of the light are not limited thereto. Note that the light transmitted through the light-transmissive member 61 may be directly extracted without providing the reflecting mirror 65.

### Members Serving as Path of First Current

Next, examples of members serving as the path of the first current for detecting whether or not the lens 50 is disposed on the step member 13 will be described. Examples of the members serving as the path of the first current include the first terminal 71, the second terminal 72, the first conductor 81, the second conductor 82, and the third conductor 83. In the present embodiment, the fourth conductor 84 and the fifth conductor 85 are further included in the members serving as the path of the first current. Each of the first terminal 71, the second terminal 72, the first conductor 81, the second conductor 82, the third conductor 83, the fourth conductor 84, and the fifth conductor 85 may be formed of a single metal material such as gold, silver, aluminum, nickel, rhodium, copper, titanium, platinum, palladium, molybdenum, chromium, or tungsten, or an alloy material containing any of these metals.

The first terminal 71 is electrically connected to an external detection circuit. Here, examples of the external detection circuit include an electronic circuit such as a microcomputer, which includes a processor such as a central processing unit (CPU) and a storage medium such as a memory. As illustrated in FIGS. 1 and 2, the main body 11 of the base 10 is provided with the first terminal 71. In the example illustrated in FIGS. 1 and 2, the first terminal 71 is a rod-shaped metal member provided at the lateral surface 11c on the −X side of the main body 11. In addition, the first terminal 71 extends inside the main body 11 and reaches the inner layer wiring 15a. However, the configuration such as the location, the size, and the shape of the first terminal 71 is not limited thereto.

The first conductor 81 is electrically connected to, for example, the inner layer wiring 15a. That is, the first conductor 81 is electrically connected to the first terminal 71 through the inner layer wiring 15a. As illustrated in FIGS. 2 to 4, the first conductor 81 is disposed on the upper surface 131a of the first step member 131. In addition, a portion (a portion on the −Y side) of the first conductor 81 overlaps the planar portion 51 of the lens 50 in a top view. In the example illustrated in FIG. 2, a portion of the first conductor 81 overlaps the end portion of the planar portion 51 on the −X side in a top view. However, the first conductor 81 does not necessarily have to extend to a location overlapping the planar portion 51 of the lens 50 in a top view. For example, the first conductor 81 may extend to a location in contact with the second conductor 82 and may terminate at the location in contact with the second conductor 82. The first conductor 81 is electrically connected to the second conductor 82.

In the example illustrated in FIGS. 2 to 4, the second conductor 82 is disposed on the lens lateral surface 53. However, the second conductor 82 may be disposed on the lens lateral surface 54. The second conductor 82 extends parallel to the center line 50M of the lens 50 in a top view. In addition, the second conductor 82 is electrically connected to each of the first conductor 81 and the third conductor 83. In more detail, as illustrated in FIG. 2, the second conductor 82 extends to an end portion of the lens lateral surface 53 on the −X side and is bonded to the first conductor 81. In addition, the second conductor 82 extends to an end portion of the lens lateral surface 53 on the +X side and is bonded to the third conductor 83.

The second conductor 82 is not disposed on the planar portion 51 and the convex surface portion 52 of the lens 50. With this configuration, the second conductor 82 can be disposed without blocking the optical path of the light reaching the lens 50 from the light-reflecting member 40 and the light passing through the lens 50 and traveling toward the light-transmissive member 61.

The third conductor 83 is electrically connected to the second conductor 82. As illustrated in FIG. 2, the third conductor 83 is disposed on the upper surface 132a of the second step member 132. A portion (a portion on the −Y side) of the third conductor 83 overlaps the planar portion 51 of the lens 50 in a top view. In the example illustrated in FIG. 2, a portion of the third conductor 83 overlaps the +X side of the planar portion 51. However, the third conductor 83 does not necessarily have to extend to a location overlapping the planar portion 51 of the lens 50 in a top view. For example, the third conductor 83 may extend to a location in contact with the second conductor 82 and may terminate at the location in contact with the second conductor 82. The third conductor 83 is electrically connected to the second conductor 82. The third conductor 83 is electrically connected to the inner layer wiring 15b provided in the main body 11 of the base 10.

The fourth conductor 84 is provided on the planar portion 51 of the lens 50. The fourth conductor 84 is disposed between the upper surface 131a of the first step member 131 and the planar portion 51. In addition, the fourth conductor 84 is electrically connected to the first conductor 81, the second conductor 82, and the third conductor 83. The fourth conductor 84 is in contact with the second conductor 82. In addition, the fourth conductor 84 may be disposed on the first conductor 81. Because the fourth conductor 84 is disposed between the upper surface 131a of the first step member 131 and the planar portion 51, adhesion between the lens 50 and the first conductor 81 can be improved. In a case in which the first conductor 81 does not extend to a location overlapping the planar portion 51 in a top view, when the fourth conductor 84 is disposed between the upper surface 131a of the first step member 131 and the planar portion 51, adhesion between the lens 50 and the upper surface 131a of the first step member 131 can be improved.

The fifth conductor 85 is provided on the planar portion 51 of the lens 50. The fifth conductor 85 is disposed between the upper surface 132a of the second step member 132 and the planar portion 51. In addition, the fifth conductor 85 is electrically connected to the first conductor 81, the second conductor 82, and the third conductor 83. The fifth conductor 85 is in contact with the second conductor 82. In addition, the fifth conductor 85 may be disposed on the third conductor 83. Because the fifth conductor 85 is disposed between the upper surface 132a of the second step member 132 and the planar portion 51, adhesion between the lens 50 and the third conductor 83 can be improved. In a case in which the third conductor 83 does not extend to a location overlapping the planar portion 51 in a top view, by disposing the fifth conductor 85 between the upper surface 132a of the second step member 132 and the planar portion 51, adhesion between the lens 50 and the upper surface 132a of the second step member 132 can be improved.

The second terminal 72 is electrically connected to an external first power source. Note that, in FIGS. 1 and 2, illustration of the first power source is omitted.

The main body 11 of the base 10 is provided with the second terminal 72. In the example illustrated in FIGS. 1 and 2, the second terminal 72 is a rod-shaped metal member provided at the lateral surface 11c of the main body 11 on the +X side. The second terminal 72 extends inside the main body 11 and reaches the inner layer wiring 15b. That is, the second terminal 72 is electrically connected to the third conductor 83 through the inner layer wiring 15b. However, the configuration such as the location, the size, and the shape of the second terminal 72 is not limited thereto.

When the lens 50 is disposed on the step member 13, that is, when the lens 50 is supported by each of the upper surface 131a of the first step member 131 and the upper surface 132a of the second step member 132 and is located on the +Z side of the light-reflecting member 40, the first terminal 71, the first conductor 81, the second conductor 82, the third conductor 83, and the second terminal 72 are electrically connected to each other. Thus, the first current from the first power source flows to the external detection circuit through the second terminal 72, the third conductor 83, the second conductor 82, the first conductor 81, and the first terminal 71. Thus, the external detection circuit detects that the lens 50 is disposed on the step member 13. Note that the direction of the first current is not limited thereto.

In contrast, when the lens 50 is separated from the step member 13, that is, when the lens 50 is separated from at least one of the upper surface 131a of the first step member 131 and the upper surface 132a of the second step member 132, the path of the first current does not reach the first conductor 81 and is interrupted in the middle. Thus, the first current from the first power source does not reach the external detection circuit. Thus, the external detection circuit detects that the lens 50 is separated from the step member 13. As a result, the lens 50 not being located on the +Z side of the light-reflecting member 40 can be quickly detected.

As illustrated in FIG. 2, because the lens 50 is supported by each of the upper surface 131a of the first step member 131 and the upper surface 132a of the second step member 132, the path of the first current from the first power source to the external detection circuit can be easily provided using the arrangement region of the lens 50. In addition, only by flowing the first current from the first power source to the external detection circuit, the lens 50 being disposed on the step member 13 can be detected. That is, a circuit configuration for detecting that the lens 50 is disposed on the step member 13 can be simplified.

Furthermore, each of a portion of the first conductor 81 overlapping the planar portion 51 in a top view, the second conductor 82, and a portion of the third conductor 83 overlapping the planar portion 51 in a top view is located in a region of the planar portion 51 of the lens 50 excluding a region on which the light reflected by the light-reflecting member 40 is incident. The fourth conductor 84 and the fifth conductor 85 are also disposed in the region of the planar portion 51 of the lens 50 excluding the region on which the light reflected by the light-reflecting member 40 is incident. Therefore, the light reaching the lens 50 from the light-reflecting member 40 is not blocked by the members serving as the path of the first current, such as the first conductor 81, the second conductor 82, the third conductor 83, the fourth conductor 84, and the fifth conductor 85. Furthermore, each of the first conductor 81, the second conductor 82, the third conductor 83, the fourth conductor 84, and the fifth conductor 85 is not disposed on the convex surface portion 52 of the lens 50. Therefore, the light having transmitted through the lens 50 and exiting from the convex surface portion 52 is not blocked by the members serving as the path of the first current, such as the first conductor 81, the second conductor 82, the third conductor 83, the fourth conductor 84, and the fifth conductor 85.

In the example illustrated in FIG. 2, the first current is supplied from the second terminal 72 and flows to the first terminal 71 through each of the members serving as the path of the first current. However, the direction of the first current is not limited thereto. For example, the first current may be supplied from the first terminal 71 and may flow to the second terminal 72 through the members serving as the path of the first current. That is, the first terminal 71 may be electrically connected to the first power source, and the second terminal 72 may be electrically connected to the external detection circuit.

### Members Disposed in Path of Second Current

Next, examples of members serving as the path through which the second current for supplying power to the semiconductor laser element 20 flows will be described. Examples of the members serving as the path of the second current include the third terminal 73, the fourth terminal 74, the sixth conductor 86, and the seventh conductor 87. Each of the third terminal 73, the fourth terminal 74, the sixth conductor 86, and the seventh conductor 87 may be formed of a single metal material such as gold, silver, aluminum, nickel, rhodium, copper, titanium, platinum, palladium, molybdenum, chromium, or tungsten, or an alloy material containing any of these metals.

The third terminal 73 is electrically connected to an external second power source. Note that, in FIGS. 1 and 2, illustration of the second power source is omitted. As illustrated in FIGS. 1 and 2, the main body 11 of the base 10 is provided with the third terminal 73. In the example illustrated in FIGS. 1 and 2, the third terminal 73 is a rod-shaped metal member provided at the lateral surface 11c of the main body 11 on the −Y side. The third terminal 73 extends inside the main body 11 and reaches the inner layer wiring 15c. However, the configuration such as the location, the size, and the shape of the third terminal 73 is not limited thereto.

The sixth conductor 86 is disposed on the upper surface 131a of the first step member 131. For example, the sixth conductor 86 is electrically connected to the third terminal 73 through the inner layer wiring 15c. The sixth conductor 86 is electrically connected to the first electrode 22 of the semiconductor laser element 20 through the fine conductive wire 91.

As illustrated in FIG. 2, the sixth conductor 86 of the present embodiment is separated from the first conductor 81 and the fourth conductor 84 and disposed on the upper surface 131a of the first step member 131. That is, in the example illustrated in FIG. 2, the sixth conductor 86 is electrically independent from each of the first conductor 81, the second conductor 82, the third conductor 83, the fourth conductor 84, and the fifth conductor 85.

The seventh conductor 87 is disposed on the upper surface 132a of the second step member 132. The seventh conductor 87 is electrically connected to the second electrode 23 of the semiconductor laser element 20 through the fine conductive wire 92 and the bonding member 35. The seventh conductor 87 is electrically connected to the inner layer wiring 15d provided in the main body 11 of the base 10.

As illustrated in FIG. 2, the seventh conductor 87 is separated from the third conductor 83 and the fifth conductor 85 and disposed on the upper surface 132a of the second step member 132. That is, in the example illustrated in FIG. 2, the seventh conductor 87 is electrically independent from each of the first conductor 81, the second conductor 82, the third conductor 83, the fourth conductor 84, and the fifth conductor 85.

The third terminal 73 is electrically connected to an external electrode. Note that, in FIGS. 1 and 2, illustration of the external electrode is omitted. The main body 11 of the base 10 is provided with the fourth terminal 74. In the example illustrated in FIGS. 1 and 2, the fourth terminal 74 is a rod-shaped metal member provided at the lateral surface 11c of the main body 11 on the −Y side. The third terminal 73 and the fourth terminal 74 are separated from each other and disposed at the same lateral surface 11c of the main body 11 on the −Y side.

The fourth terminal 74 extends inside the main body 11 and reaches the inner layer wiring 15d. That is, the fourth terminal 74 is electrically connected to the seventh conductor 87 through the inner layer wiring 15d. However, the configuration such as the location, the size, and the shape of the fourth terminal 74 is not limited thereto.

With the third terminal 73, the sixth conductor 86, the seventh conductor 87, and the fourth terminal 74, the path of the second current that flows from the second power source to the external electrode through the semiconductor laser element 20 can be easily provided.

In the example illustrated in FIG. 2, the second current is supplied from the fourth terminal 74 and flows to the third terminal 73 through each of the members serving as the path of the second current. However, the direction of the second current is not limited thereto. For example, the second current may be supplied from the third terminal 73 and flow to the fourth terminal 74 through each of the members serving as the path of the second current. That is, the third terminal 73 may be electrically connected to the second power source, and the fourth terminal 74 may be electrically connected to the external electrode.

### First Modified Example

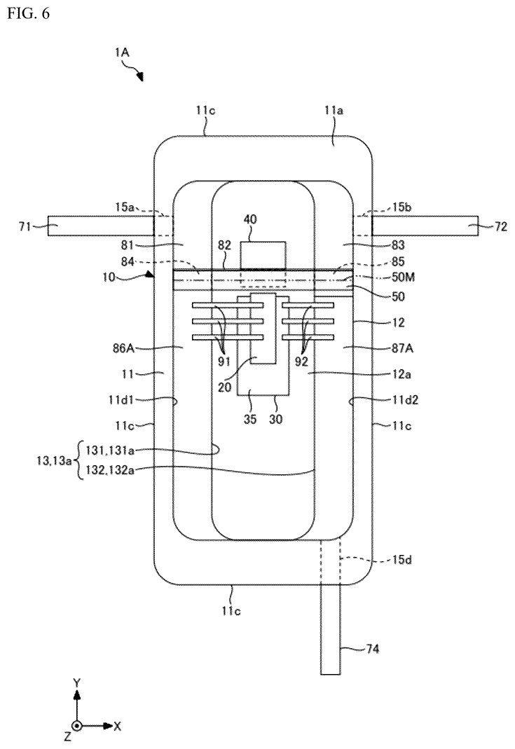

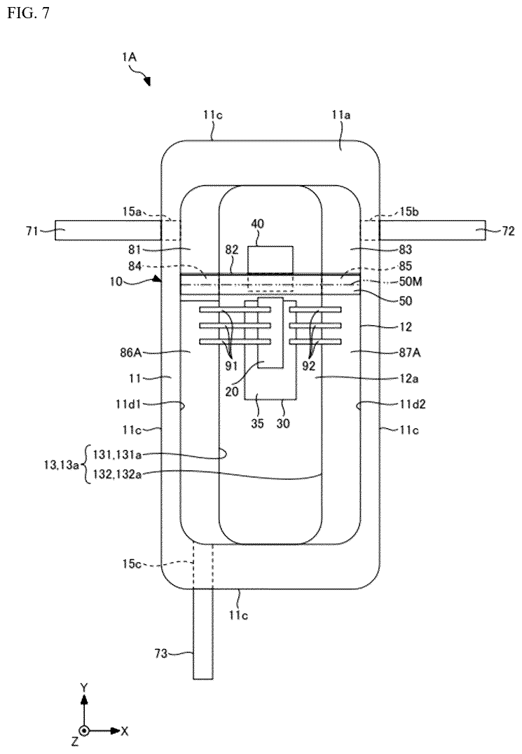

Next, a configuration example of a light-emitting device 1A according to a first modified example of the embodiment will be described with reference to FIGS. 6 and 7. FIG. 6 is a schematic top view illustrating the light-emitting device 1A according to the first modified example. FIG. 7 is a schematic top view illustrating another example of the light-emitting device 1A according to the first modified example. Note that, in the light-emitting device 1A according to the first modified example, substantially the same members as those of the light-emitting device 1 according to the embodiment are denoted by the same reference characters, and descriptions thereof will be omitted as appropriate. In FIGS. 6 and 7, illustration of the first power source, the second power source, the external detection circuit, and the external electrode is omitted. In addition, in FIGS. 6 and 7, illustration of the light-transmissive member 61 and the reflecting mirror 65 is omitted.

In the first modified example, the path through which the second current for supplying power to the semiconductor laser element 20 flows is different from that in the embodiment. In more detail, a sixth conductor 86A disposed on the upper surface 131a of the first step member 131 of the base 10 is electrically connected to at least one of the first conductor 81 and the fourth conductor 84 also disposed on the upper surface 131a of the first step member 131. In this case, for example, the first conductor 81 and the sixth conductor 86A may be monolithically formed. A seventh conductor 87A is disposed at a location separated from the third conductor 83 and the fifth conductor 85.

Because at least the sixth conductor 86A is continuous with at least one of the first conductor 81 and the fourth conductor 84, the first current flowing from the first power source to the first terminal 71 through the second terminal 72 and the second current flowing from the second power source to the first terminal 71 through the fourth terminal 74 partially share the current paths thereof. In addition, the light-emitting device 1A does not necessarily have to include the third terminal 73 electrically connected to the second power source. Thus, the manufacturing cost of the light-emitting device 1A can be reduced.

Further, as illustrated in FIG. 7, the third terminal 73 may be disposed without disposing the fourth terminal 74, and a part of the first current may flow from the second terminal 72 to the third terminal 73. As illustrated in FIG. 7, the seventh conductor 87A is electrically connected to at least one of the third conductor 83 and the fifth conductor 85. In this case, for example, the third conductor 83 and the seventh conductor 87A may be monolithically formed. The sixth conductor 86A is disposed at a location separated from the first conductor 81 and the fourth conductor 84. With such a structure, a part of the first current flowing from the first power source to at least one of the third conductor 83 and the fifth conductor 85 through the second terminal 72 can flow to the seventh conductor 87A. A part of the first current flowing to the seventh conductor 87A flows to the external electrode through the semiconductor laser element 20, the sixth conductor 86A, and the third terminal 73. That is, a part of the first current can be diverted as the second current. In addition, because at least the seventh conductor 87A is continuous with at least one of the third conductor 83 and the fifth conductor 85, the first current flowing from the first power source to the first terminal 71 through the second terminal 72 and the second current flowing from the first power source to the third terminal 73 through the second terminal 72 partially share the current paths thereof. The light-emitting device 1A does not necessarily have to include the fourth terminal 74 electrically connected to the second power source. Thus, the manufacturing cost of the light-emitting device 1A can be reduced.

### Second Modified Example

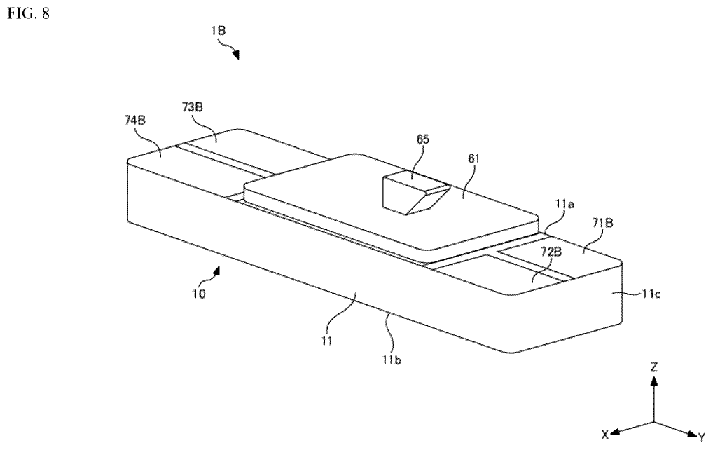

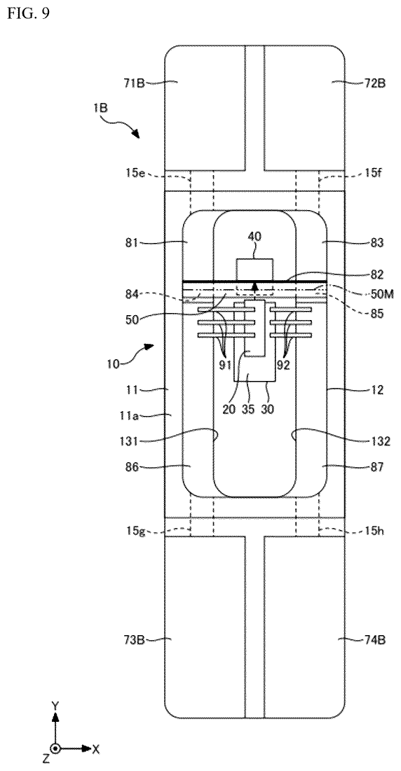

Next, a configuration example of a light-emitting device 1B according to a second modified example of the embodiment will be described with reference to FIGS. 8 and 9. FIG. 8 is a schematic perspective view illustrating the light-emitting device 1B according to the second modified example. FIG. 9 is a schematic top view illustrating the light-emitting device 1B according to the second modified example. Note that, in the light-emitting device 1B according to the second modified example, substantially the same members as those of the embodiment described above are denoted by the same reference characters, and descriptions thereof will be omitted as appropriate. In FIGS. 8 and 9, illustration of the first power source, the second power source, the external detection circuit, and the external electrode is omitted. In FIG. 9, illustration of the light-transmissive member 61 and the reflecting mirror 65 is omitted.

In the light-emitting device 1B, the configurations of a first terminal 71B, a second terminal 72B, a third terminal 73B, and a fourth terminal 74B are mainly different from the configurations of the first terminal 71, the second terminal 72, the third terminal 73, and the fourth terminal 74 of the light-emitting device 1.

Specifically, as illustrated in FIGS. 8 and 9, each of the first terminal 71B, the second terminal 72B, the third terminal 73B, and the fourth terminal 74B is, for example, a film-shaped conductor. Examples of the materials constituting the first terminal 71B, the second terminal 72B, the third terminal 73B, and the fourth terminal 74B include a single metal material such as gold, silver, aluminum, nickel, rhodium, copper, titanium, platinum, palladium, molybdenum, chromium, or tungsten, or an alloy material containing any of these metals.

The first terminal 71B is electrically connected to, for example, the first power source. The second terminal 72B is electrically connected to, for example, the external detection circuit. However, the first terminal 71B may be electrically connected to the external detection circuit, and the second terminal 72B may be electrically connected to the first power source. The third terminal 73B is electrically connected to, for example, the second power source. The fourth terminal 74B is electrically connected to the external electrode. However, the third terminal 73B may be electrically connected to the external electrode, and the fourth terminal 74B may be electrically connected to the second power source.

The first terminal 71B, the second terminal 72B, the third terminal 73B, and the fourth terminal 74B are disposed on the upper surface 11a of the main body 11 of the base 10. In a top view, the first terminal 71B and the second terminal 72B are disposed on the +Y side with respect to the recessed portion 12. As illustrated in FIG. 9, the first terminal 71B is electrically connected to the first conductor 81 through, for example, an inner layer wiring 15e disposed inside the main body 11. The second terminal 72B is electrically connected to the third conductor 83 through, for example, an inner layer wiring 15f disposed inside the main body 11.

In a top view, the third terminal 73B and the fourth terminal 74B are disposed on the −Y side with respect to the recessed portion 12. As illustrated in FIG. 9, the third terminal 73B is electrically connected to the sixth conductor 86 through, for example, an inner layer wiring 15g disposed inside the main body 11. The fourth terminal 74B is electrically connected to the seventh conductor 87 through, for example, an inner layer wiring 15h disposed inside the main body 11. Note that, each of the first terminal 71B, the second terminal 72B, the third terminal 73B, and the fourth terminal 74B may be provided on, for example, the lower surface 11b of the base 10. Each of the first terminal 71B, the second terminal 72B, the third terminal 73B, and the fourth terminal 74B may be provided, for example, on the lateral surface 11c of the base 10.

In the light-emitting device 1B, by forming the first terminal 71B, the second terminal 72B, the third terminal 73B, and the fourth terminal 74B as film-shaped conductors disposed on the upper surface 11a of the main body 11 of the base 10, the size of the light-emitting device 1B in the first direction Y and the second direction X can be reduced. As a result, the size of the light-emitting device 1B can be reduced. In addition, for example, because each of the first terminal 71B, the second terminal 72B, the third terminal 73B, and the fourth terminal 74B can be formed on the upper surface 11a by a simple film forming method such as a sputtering method, the cost of manufacturing the light-emitting device 1B can be reduced.

### Third Modified Example

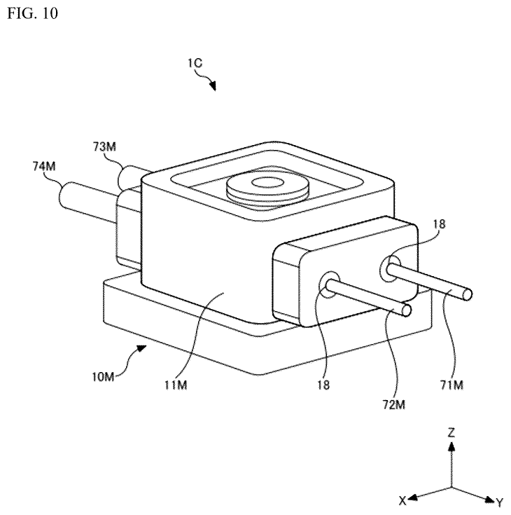

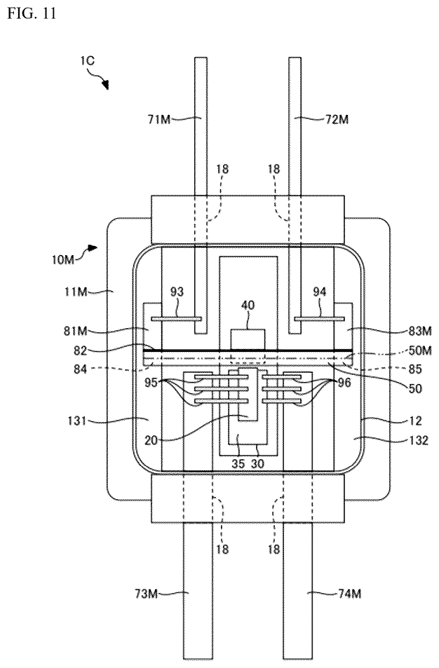

Next, a configuration example of a light-emitting device 1C according to a third modified example of the embodiment will be described with reference to FIGS. 10 and 11. FIG. 10 is a schematic perspective view illustrating the light-emitting device 1C according to the third modified example. FIG. 11 is a schematic top view illustrating the light-emitting device 1C according to the third modified example. Note that, in the light-emitting device 1C according to the third modified example, substantially the same members as those of the embodiment described above are denoted by the same reference characters, and descriptions thereof will be omitted as appropriate. In FIGS. 10 and 11, illustration of the first power source, the second power source, the external detection circuit, and the external electrode is omitted.

In the light-emitting device 1C, the configuration of a main body 11M of a base 10M, the configuration of the members serving as the path of the first current, and the configuration of the members serving as the path of the second current are mainly different from the configuration of the main body 11 of the base 10, the configuration of the members serving as the path of the first current, and the configuration of the members serving as the path of the second current in the embodiment.

Specifically, the main body 11M is further provided with a plurality of through holes 18, each of which is connected to the recessed portion 12. A first terminal 71M, a second terminal 72M, a third terminal 73M, and a fourth terminal 74M are respectively inserted into the plurality of through holes 18. As a result, a portion of the first terminal 71M, a portion of the second terminal 72M, a portion of the third terminal 73M, and a portion of the fourth terminal 74M are disposed in the recessed portion 12.

The main body 11M is preferably formed of a single metal material such as gold, silver, aluminum, nickel, rhodium, copper, titanium, platinum, palladium, molybdenum, chromium, or tungsten, or an alloy material containing any of these metals. However, the main body 11M may be formed of a material other than metals, for example, a ceramic such as aluminum nitride, silicon nitride, aluminum oxide, or silicon carbide, or any other material.

The first terminal 71M and a first conductor 81M are electrically connected to each other through a fine conductive wire 93. The second terminal 72M and a third conductor 83M are electrically connected to each other through a fine conductive wire 94. The third terminal 73M and the semiconductor laser element 20 are electrically connected to each other through a fine conductive wire 95. The fourth terminal 74M and the semiconductor laser element 20 are electrically connected to each other through a fine conductive wire 96 and the bonding member 35. In the light-emitting device 1C, for example, the sixth conductor 86 and the seventh conductor 87 included in the light-emitting devices 1, 1A, and 1B are not provided.

The first terminal 71M is electrically connected to, for example, the first power source. The second terminal 72M is electrically connected to, for example, the external detection circuit. However, the first terminal 71M may be electrically connected to the external detection circuit, and the second terminal 72M may be electrically connected to the first power source. The third terminal 73M is electrically connected to, for example, the second power source. The fourth terminal 74M is electrically connected to the external electrode. However, the third terminal 73M may be electrically connected to the external electrode, and the fourth terminal 74M may be electrically connected to the second power source.

In the light-emitting device 1C, it is possible to flow the first current from the first power source to the external detection circuit without providing an inner layer wiring in the main body 11M of the base 10M. In addition, it is possible to flow the second current from the second power source to the external electrode without providing an inner layer wiring in the main body 11M of the base 10M. With this configuration, the configuration of each of the main body 11M, the members serving as the path of the first current, and the members serving as the path of the second current can be simplified.

Although the preferred embodiments and the like have been described in detail above, the disclosure is not limited to the above-described embodiments and the like, various modifications and substitutions can be made to the above-described embodiments and the like without departing from the scope described in the claims.

What is claimed is:

1. A light-emitting device comprising:
a base including
a main body defining a recessed portion opening at an upper surface of the main body, and
a step member provided inside the recessed portion, extending along an inner lateral surface of the recessed portion, and disposed between a bottom surface of the recessed portion and the upper surface of the main body in a height direction;
a semiconductor laser element disposed between the bottom surface of the recessed portion and an upper surface of the step member in the height direction, and configured to emit laser light;
a support member disposed on the bottom surface of the recessed portion and supporting the semiconductor laser element;
a light-reflecting member disposed on the bottom surface of the recessed portion, separated from the support member and the semiconductor laser element, and configured to reflect upwardly the laser light emitted by the semiconductor laser element; and
a lens disposed on the upper surface of the step member such that the lens is located above the light-reflecting member, the lens including
a planar portion including a region overlapping the upper surface of the step member and a region overlapping the light-reflecting member in a top view, and a region on which the laser light having been reflected by the light-reflecting member is incident, and
a convex surface portion located above the planar portion, and including a region through which the laser light incident from the planar portion exits, wherein
when, in the top view, an elongated direction of the step member is referred to as a first direction, a length of the lens in the first direction is shorter than a length of the lens in a second direction orthogonal to the first direction, and
in the top view, at least a portion of the semiconductor laser element does not overlap the lens.

2. The light-emitting device according to claim 1, wherein the length of the lens in the first direction in the top view is at least twice a length in the height direction from the bottom surface of the recessed portion to an optical axis of the laser light emitted by the semiconductor laser element.

3. The light-emitting device according to claim 1, wherein the lens is configured to reduce a divergence angle of a light travelling in the first direction more than a divergence angle of a light travelling in the second direction in the laser light incident on the planar portion of the lens.

4. The light-emitting device according to claim 1, wherein
the step member includes a first step member and a second step member with the semiconductor laser element being interposed between the first step member and the second step member in the top view, and
the planar portion of the lens includes a region overlapping an upper surface of the first step member and a region overlapping an upper surface of the second step member in the top view.

5. The light-emitting device according to claim 1, wherein the light-reflecting member includes a region overlapping the lens and a region not overlapping the lens, in the top view.

6. The light-emitting device according to claim 1, further comprising:
a light-transmissive member overlapping the recessed portion of the base in the top view, wherein
each of the semiconductor laser element, the light-reflecting member, and the lens is accommodated in a space defined by the recessed portion and the light-transmissive member.

7. The light-emitting device according to claim 4, further comprising:
a first terminal attached to the main body;
a first conductor electrically connected to the first terminal, and disposed on the upper surface of the first step member;
a second conductor electrically connected to the first conductor, and disposed on a lateral surface of the lens, the lateral surface of the lens connecting the planar portion and the convex surface portion;
a third conductor electrically connected to the second conductor, and disposed on the upper surface of the second step member; and
a second terminal attached to the main body, the second terminal being electrically connected to the third conductor.

8. The light-emitting device according to claim 7, wherein
a portion of the first conductor overlaps the planar portion of the lens in the top view,
a portion of the third conductor overlaps the planar portion of the lens in the top view, and
the portion of the first conductor, the second conductor, and the portion of the third conductor are located in a region of the planar portion of the lens excluding a region on which the laser light reflected by the light-reflecting member is incident.

9. The light-emitting device according to claim 7, further comprising:
a fourth conductor disposed between the upper surface of the first step member and the planar portion of the lens, and electrically connected to the first conductor, the second conductor, and the third conductor;
a fifth conductor disposed between the upper surface of the second step member and the planar portion of the lens, and electrically connected to the first conductor, the second conductor, and the third conductor;
a sixth conductor disposed on the upper surface of the first step member; and
a seventh conductor disposed on the upper surface of the second step member, wherein
the semiconductor laser element includes a first electrode and a second electrode,
the sixth conductor is electrically connected to the first electrode of the semiconductor laser element, and
the seventh conductor is electrically connected to the second electrode of the semiconductor laser element.

10. The light-emitting device according to claim 9, wherein at least one of the sixth conductor and the seventh conductor is electrically independent from each of the first conductor, the second conductor, the third conductor, the fourth conductor, and the fifth conductor.

11. The light-emitting device according to claim 10, wherein both of the sixth conductor and the seventh conductor are electrically independent from each of the first conductor, the second conductor, the third conductor, the fourth conductor, and the fifth conductor.

12. The light-emitting device according to claim 1, wherein, in the height direction, an upper end of the light-reflecting member is located below the upper surface of the step member.

13. The light-emitting device according to claim 1, wherein, in the height direction, a most protruding portion of the convex surface portion of the lens is located below the upper surface of the main body of the base.
